(19) United States
(12) Patent Application Publication
(10) Pub. No.: US 2011/0101829 A1
(43) Pub. Date: May 5, 2011

(54) Piezoelectric Multilayer Component

(76) Inventors: Oliver Dernovsek, Graz (AT); Alexander Glazunov, Deutschlandsberg (AT)

(21) Appl. No.: 12/839,638

(22) Filed: Jul. 20, 2010

Related U.S. Application Data
(63) Continuation of application No. PCT/EP2009/000393, filed on Jan. 22, 2009.

(30) Foreign Application Priority Data
Jan. 23, 2008 (DE) 10 2008 005 681.2

(51) Int. Cl. H01L 41/083; H01L 41/24

(52) U.S. Cl. 310/363; 29/25.35

(57) ABSTRACT

A piezoelectric multilayer component includes a stack of green piezoceramic layers which are arranged one on top of the other. A first electrode layer is applied to a piezoceramic layer and contains a first metal. A second electrode layer is applied to a further piezoceramic layer and is adjacent to the first electrode layer in the stacking direction. The second electrode layer contains a higher concentration of the first metal than does the first electrode layer.

This application is a continuation of co-pending International Application No. PCT/EP2009/000393, filed Jan. 22, 2009, which designated the United States and was not published in English, and which claims priority to German Application No. 10 2008 005 681.2 filed Jan. 23, 2008, both of which applications are incorporated herein by reference.

### TECHNICAL FIELD

A method is specified for producing a piezoelectric multilayer component, as well as a piezoelectric multilayer component which can be produced by means of the method and has an area of reduced mechanical robustness.

### BACKGROUND

German patent document DE 10 2006 031 085 A1, and counterpart U.S. Publication 2009/0289527, disclose a piezoelectric multilayer component having weak layers.

### SUMMARY

In one aspect, the present invention specifies a piezoelectric multilayer component that can be operated in a stable form over as long a time period as possible.

A piezoelectric multilayer component is specified as an intermediate product having a stack of green piezoceramic layers which are arranged one on top of the other, wherein a first electrode layer is applied to a piezoceramic layer and contains a first metal. A second electrode layer is applied to a further piezoceramic layer and is adjacent to the first electrode layer in the stacking direction. The second electrode layer contains a higher concentration of the first metal than does the first electrode layer. The term “concentration” in this case refers to the proportion by weight of the metal in the respective electrode layer.

If the intermediate product is sintered, the first metal partially diffuses from the second electrode layer to the first electrode layer and in the process leaves cavities in the second electrode layer. The concentration difference of the first metal is in this case selected such that the second electrode layer can still serve as electrode layer in the operation of the multilayer component, until the multilayer component cracks in the second electrode layer under specific mechanical loads. The second electrode layer thus also serves as a weak layer.

The concentration of the first metal in the first electrode layer is less than 100%. In this case, it is preferable for the concentration of the first metal in the first electrode layer to be up to 80%.

It has been found that copper is particularly suitable for use as the first metal since it softens at relatively low temperatures, and protective sintering of the piezoelectric multilayer component is therefore possible, during which the copper binds well with a piezoceramic layer. Furthermore, it has been found that copper, in comparison to other metals such as palladium or platinum, diffuses relatively easily through a piezoceramic. This makes it easier to produce a piezoelectric multilayer component, as described in the following text, with a mechanically weakened area that has cavities and serves as a weak electrode layer.

A different metal, such as silver or nickel, can be used instead of copper as the first metal.

According to one embodiment, the first electrode layer contains an additional, second metal, which is different from the first metal.

It is preferable for the second metal to diffuse less well than the first metal through a piezoceramic layer which is adjacent to the first electrode layer. The diffusion of metal through the multilayer component is therefore achieved predominantly by the first metal, in particular by copper.

The second metal is preferably selected from palladium, beryllium, aluminum, manganese, zinc, tin, bismuth, nickel, cobalt, chromium, molybdenum, niobium, rubidium, depending on what metal is used as the first metal in the first electrode layer.

It is advantageous for the concentration of the first metal in the first electrode layer to be higher than is the second metal. For example, the concentration of the first metal can be 70% and the concentration of the second metal can be 30% in the first electrode layer. In this case, it is important for the concentration of the first metal in the first electrode layer to be lower than the concentration of the first metal in the second electrode layer, thus allowing diffusion from the second electrode layer to the first electrode layer. The diffusion of the first metal reduces its concentration difference between the first electrode layer and the second electrode layer, that is to say the concentration of the first metal in the second electrode layer, decreases naturally.

According to one embodiment, the second electrode layer contains exclusively the first metal as metal. The second electrode layer can therefore, for example, contain only copper as a metal. However, it can also contain a mixture of copper (as the first metal) and, for example, nickel oxide or an alloy of copper and nickel. In this case, the copper-nickel alloy should be considered to be the first metal.

Metals that have different diffusion rates in the piezoelectric ceramic material are preferably used in the first and in the second electrode layers, in order to ensure that the diffusion takes place in a preferred manner in one direction, as a result of which only one type of electrode layers is depleted of a material, and is thus mechanically weakened.

The difference in the concentration of the first metal between the first electrode layer and the second electrode layer is preferably set such that, when the multilayer component is heated, diffusion of the first metal from the second electrode layer leads to a loss of material in the second electrode layer. In this case, the concentration difference, that is to say the concentration of the first metal in the first electrode layer in comparison to the concentration of the first metal in the second electrode layer, is set such that the second electrode layer remains structurally intact after migration of a proportion of the first metal. The second electrode layer can therefore act as an electrode layer during operation of the multilayer component.

In contrast, excessive material loss from the second electrode layer would lead to it, together with a piezoceramic layer and an electrode layer of opposite polarity, no longer being able to build up a significant electrical field, as a result of which a piezoceramic adjacent to the second electrode layer would also not be able to expand. The performance of the piezoelectric multilayer component during operation would therefore decrease.

In particular, the concentration difference is set such that an electrical connection remains between the second electrode layer and an external contact, which may be applied on one side of the stack. The electrical connection between an external contact and a second electrode layer should therefore not be interrupted by the diffusion of the first metal.

It is preferable for the piezoceramic layers of the piezoelectric multilayer component to contain a PZT (lead-zirconate-titanate) ceramic. It has been found that metals, in particular copper, can diffuse with relatively little resistance through an PZT ceramic during the sintering of the piezoelectric multilayer component. The diffusion process of a metal between two areas of the piezoelectric multilayer component, in which the first metal is present in different concentrations, can thus be promoted.

According to one embodiment, the intermediate product comprises a piezoelectric ceramic and electrode layers located therebetween, wherein a first electrode layer contains a first metal as a main component with a proportion by weight of more than 50%. The first electrode layer contains a second metal, which is not the same as the first metal, as a secondary component with a proportion by weight of less than 50%, wherein, with respect to the diffusion of the metals, the first metal has a higher mobility in the ceramic material than does the second metal. The second electrode layer is preferably adjacent to the first in the stacking direction, wherein the second electrode layer contains the first metal as a main component with a proportion by weight which is greater than the corresponding proportion by weight in the first electrode layer.

Furthermore, a method is specified for producing a piezoelectric multilayer component, in which an intermediate product described here is sintered, wherein the first metal diffuses partially from the second electrode layer to the first electrode layer and in the process leaves cavities in the second electrode layer, thus mechanically weakening the second electrode layer.

During operation of the piezoelectric multilayer component, the mechanically weakened second electrode layer can be used as a weak layer by means of which, for example, when specific tension loads occur in the multilayer component, a controlled crack can run parallel to the piezoceramic layers, or to the electrode layers.

Adjacent piezoceramic layers can be connected in the areas between the cavities, during the sintering process.

### BRIEF DESCRIPTION OF THE DRAWINGS

The described subject matters will be explained in more detail with reference to the following exemplary embodiments and figures, in which:

FIG. 1 shows a longitudinal section through a piezoactuator;

FIGS. 2a and 2b show poling cracks in a piezoactuator;

FIG. 3 shows a longitudinal section through a part of a piezoactuator, in which a first electrode layer is adjacent to a second electrode layer;

FIG. 4 shows a longitudinal section through a part of a piezoactuator with first electrode layers of opposite polarity; and

FIG. 5 shows a longitudinal section through a part of a piezoactuator with first electrode layers of the same polarity.

The following list of reference symbols can be used in conjunction with the drawings:
1 Stack of piezoceramic layers and electrode layers
2 Piezoceramic layer
3 Electrode layer
3a First electrode layer
3b Second electrode layer
4 External contact
6 Crack

### DETAILED DESCRIPTION OF ILLUSTRATIVE EMBODIMENTS

FIG. 1 shows a longitudinal section through a schematically illustrated piezoactuator, which has a stack 1 of piezoceramic layers 2 and electrode layers 3 located between them. External contacts are applied in the form of external metallizations to two longitudinal faces of the stack 1 and make electrical contact with those electrode layers 3 which are led to these longitudinal faces. Adjacent electrode layers of different polarity overlap in an orthogonal projection (which runs parallel to the stack axis of the piezoactuator). An electrical field in the overlap area, which can be referred to as active zone, leads to a piezoceramic layer 2 which is present between these electrode layers being deflected or expanded. The area in which opposite-pole adjacent electrode layers 3 do not overlap is referred to as an inactive zone. In this area, the piezoelectric effect results in virtually no deflection.

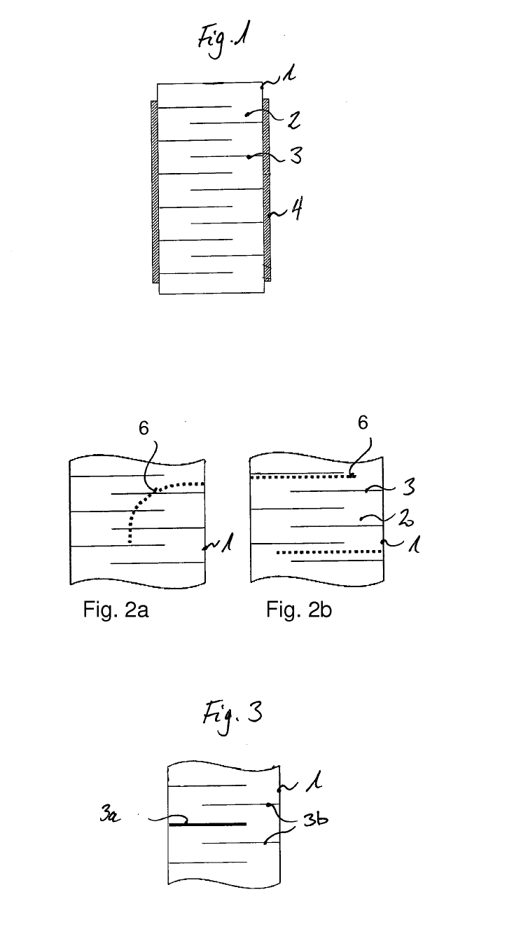

FIG. 2a shows how a crack 6 connects a plurality of electrode layers 3, in particular opposite-pole electrode layers 3 in a piezoactuator.

The inventors have found that the reliability of a piezoactuator is critically dependent on coping with any cracks that occur. During thermal processes, for example, during sintering at temperatures between 800° C. and 1500° C., metallization and soldering and during the polarization of the sintered piezoactuator, the different strain that occurs in the active and inactive zones results in mechanical stresses which lead to so-called strain-relief cracks and/or poling cracks in the piezoactuator. These run along in the inactive zone or in an electrode layer 3. These cracks can be bent at the transition to the active area. If these cracks in this case bridge at least two electrode layers, short circuits can occur which will lead to failure of the piezoactuator. Cracks which run parallel to the inner electrodes in contrast represent virtually no risk to the life cycle of piezoactuators.

FIG. 2b shows a safe profile of a crack 6 in the stack 1 of a piezoactuator. In this case, the crack runs substantially parallel to an electrode layer 3 and to a piezoceramic layer 2, as a result of which the crack does not connect opposite-polarity electrode layers, and therefore also does not cause any short circuits.

One idea to avoid damaging cracks according to FIG. 2a is to use adjacent metallic layers composed of different materials in order to stimulate diffusion processes which are intended to take place as a result of the different compositions of these metallic layers, at higher temperatures during the sintering process. During the diffusion process, a metallic layer or a component of an alloy of this layer should lose more material than the other. In the process, cavities are created in this metallic layer and will lead to mechanical weakening of this layer. Poling cracks or other cracks would therefore preferably occur in the mechanically weakened metallic layer and would only propagate there.

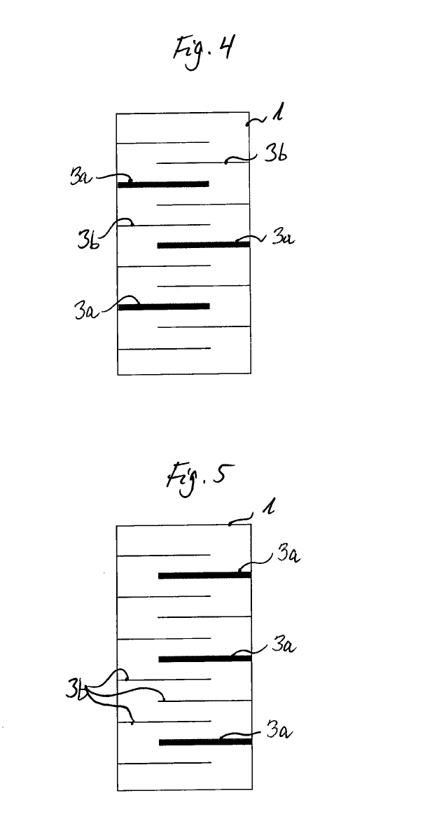

FIG. 3 shows a section of a stack 1 of a piezoelectrical multilayer component, in which a first electrode layer 3a is applied to a piezoceramic layer 2 between two second electrode layers 3b, wherein the first electrode layer 3a has a lower concentration of a first metal than do the adjacent second electrode layers 3b.

By way of example, the piezoceramic layers contain a ceramic with a composition according to the following formulae:

(PbₓNd_{y})((Zr_{1-z}Ti_{z})₁₋ₐNiₐ)O₃,

where
0.90≦x≦1.10;
0.0001≦y≦0.06;
0.35≦z≦0.60;
0≦a≦0.10.

By way of example, the second electrode layers 3b contain exclusively copper. By way of example, the first electrode layers 3a contain a material with the composition (1−x) Cu/x Pd, where 0<x<1. This material can either be a mixture of copper powder and palladium powder or an alloy of the two metals. As an alternative to this, instead of copper, it is also possible to use a different metal, such as silver. The first electrode layers 3a contain, for example, a mixture or an alloy of silver and palladium. By way of example the second electrode layers 3b contain only silver.

The difference in the composition of the first electrode layer 3a and of the second electrode layer 3b will stimulate diffusion processes at relatively high temperatures. It has been found that copper has more mobility in piezoelectric ceramics based on PZT than palladium. This leads to the diffusion taking place in only one direction, specifically from the second electrode layer 3b composed of pure copper into the first electrode layer 3a containing copper and palladium. The first electrode layer 3a, which contains copper and palladium, therefore acts as a copper sink. The material loss in the second electrode layer 3b in the immediate vicinity of the first copper-palladium electrode layer 3a leads to the formation of cavities in the second electrode layer 3b or at the boundary between the second electrode layer 3b and a surrounding or adjacent piezoceramic layer 2. Conditions are therefore created for the formation and propagation of controlled cracks, which run substantially parallel to piezoceramic layers 2.

The proportion of cavities in the second electrode layer 3b can be controlled by the composition of the first electrode layers 3a, the thickness of the first and the second electrode layer and by particle sizes of metal particles in the electrode layers.

Only a certain number of electrode layers, need in this case, a special material composition in order to stimulate diffusion processes. This simplifies the production of the piezoactuator.

During the process of sintering the piezoactuator, the second electrode layers 3b lose a certain proportion of their material, and are thus mechanically weakened. The proportion of cavities in the weakened second electrode layers 3b is in this case preferably not excessive, such that these second electrode layers remain electrically active during operation, that is to say they can be used to build up electrical fields. It is therefore preferable for the composition of the two types of electrode layers to be set such that a compromise is achieved between (a) sufficiently large cavities to achieve sufficient weakening of the second electrode layers, (b) a number of cavities which is not excessively large in the second electrode layers, in order to avoid piezoactuator performance loss during operation. If this compromise is achieved, this leads to a further advantage of the described piezoactuator: the entire volume of the piezoactuator can remain electrically active.

The second electrode layers 3b in the piezoactuator can also contain other materials instead of copper, such as an alloy of copper and some other metal, or a mixture of copper powder with another inorganic material, for example, metal or an oxide.

For example, second electrode layers 3b may be composed of a mixture or alloy of copper and nickel, or else may be composed of a mixture of copper and nickel oxide.

A more detailed description of one preferred composition of a first electrode layer will now be given. The proportion by weight of copper is 99.9% to 70%, particularly preferably with a proportion of 97% to 75%. The rest of the first electrode layer contains palladium as metal. In this case, either an alloy of copper and palladium or a mixture of copper powder and palladium powder is used.

Copper particles in the first electrode layer 3a and/or in the second electrode layer 3b have a diameter of 0.1 to 10 μm, preferably 0.4 to 1.5 μm.

Palladium particles in the first electrode layer likewise have diameters of 0.1 to 10 μm, preferably 0.4 to 1.5 μm. Other metal particles, for example, also particles of metal alloys, may likewise have these sizes.

The first electrode layers 3a and the second electrode layers 3b are preferably applied by screen printing, sputtering or spraying onto piezoceramic layers.

The thicknesses of both types of electrode layers 3a, 3b in the unsintered state of the piezoactuator is preferably between 0.1 and 20 μm, preferably 1.0 and 10 μm.

It is preferable for at least one electrode layer 3a of the first type to be fitted in the piezoactuator. It is also possible for all the electrode layers 3 of the piezoactuator, except for one, to be in the form of first electrode layers 3a, and for the remaining electrode layer to be in the form of a second electrode layer 3b. At least one weak electrode layer is therefore produced during sintering. The first electrode layers 3a, however, preferably make up 5 to 20% of the total number of electrode layers 3 which are present in the piezoactuator.

FIG. 4 shows a longitudinal section through a part of a stack 1 of a piezoactuator, in which first electrode layers 3a are led alternately to different longitudinal faces of the stack 1. The polarities of the first electrode layers 3a therefore alternate along the stacking direction, since the first electrode layers 3a alternately make contact with two different external contacts (not shown but in this context see FIG. 1).

FIG. 5 shows a longitudinal section through a part of a stack 1 of a piezoactuator, in which first electrode layers 3a are always led to the same longitudinal face of the stack along the stacking direction. The first electrode layers 3a can therefore be understood as having the same polarity, since they make contact with the same external contact (not shown, but in this context see FIG. 1).

What is claimed is:

1. A piezoelectric multilayer component, comprising:
a stack of green piezoceramic layers that are arranged one on top of the other;
a first electrode layer applied to a piezoceramic layer and containing a first metal; and
a second electrode layer applied to a further piezoceramic layer, the second electrode layer being adjacent the first electrode layer in a stacking direction, wherein the second electrode layer contains the first metal in a higher concentration than the first electrode layer.

2. The piezoelectric multilayer component as claimed in claim 1, wherein the first metal is in a concentration of up to 80% in the first electrode layer.

3. The piezoelectric multilayer component as claimed in claim 1, wherein the first metal comprises silver.

4. The piezoelectric multilayer component as claimed in claim 1, wherein the first metal comprises copper.

5. The piezoelectric multilayer component as claimed in claim 4, wherein the first metal is present in particles having diameters between 0.1 and 10 μm.

6. The piezoelectric multilayer component as claimed in claim 1, wherein the first electrode layer also contains a second metal that is different from the first metal.

7. The piezoelectric multilayer component as claimed in claim 6, wherein the second metal cannot diffuse as well as the first metal through a piezoceramic layer which is adjacent to the first electrode layer.

8. The piezoelectric multilayer component as claimed in claim 6, wherein the second metal comprises a metal selected from the group consisting of palladium, beryllium, aluminum, manganese, zinc, tin, bismuth, nickel, cobalt, chromium, molybdenum, niobium, and rubidium.

9. The piezoelectric multilayer component as claimed in claim 6, wherein the first metal is present in a higher concentration in the first electrode layer than is the second metal.

10. The piezoelectric multilayer component as claimed in claim 1, wherein the second electrode layer contains the first metal as the only metal in the second electrode layer.

11. The piezoelectric multilayer component as claimed in claim 1, wherein a difference in concentration of the first metal in the first electrode layer compared to the first metal in the second electrode layer is set such that, when the multilayer component is heated, diffusion of the first metal from the second electrode layer leads to material being lost from the second electrode layer, wherein the second electrode layer remains structurally intact, in order to allow it to act as an electrode layer during operation of the multilayer component.

12. The piezoelectric multilayer component as claimed in claim 1, wherein the piezoceramic layers each comprise a PZT ceramic.

13. A method for producing a piezoelectric multilayer component, the method comprising:
providing a component that comprises a stack of green piezoceramic layers that are arranged one on top of the other, a first electrode layer applied to a piezoceramic layer and containing a first metal, and a second electrode layer applied to a further piezoceramic layer, the second electrode layer adjacent the first electrode layer in a stacking direction, wherein the second electrode layer contains the first metal in a higher concentration than the first electrode layer; and
sintering the component so that the first metal diffuses partially from the second electrode layer into the first electrode layer thereby leaving cavities in the second electrode layer, thus mechanically weakening the second electrode layer.

14. The method as claimed in claim 13, wherein adjacent piezoceramic layers are connected between the cavities during the sintering.

15. A piezoelectric multilayer component produced directly using the method according to claim 13.

16. A method for producing a piezoelectric multilayer component, the method comprising:
arranging a stack of green piezoceramic layers one on top of the other;
applying a first electrode layer onto a piezoceramic layer, the first electrode containing a first concentration of a first metal;
applying a second electrode layer to a further piezoceramic layer, the second electrode layer adjacent the first electrode layer in a stacking direction, the second electrode layer containing a second concentration of the first metal, the second concentration being higher than the first concentration; and
performing a heating step such that the first metal diffuses partially from the second electrode layer into the first electrode layer thereby leaving cavities in the second electrode layer.

17. The method as claimed in claim 16, wherein the heating step comprises a sintering step.

18. The method as claimed in claim 16, wherein the second electrode layer remains structurally intact after the heating step so that it can serve as an electrode layer during operation of the multilayer component.
